(19) United States
(12) Patent Application Publication
(10) Pub. No.: US 2008/0197748 A1
(43) Pub. Date: Aug. 21, 2008

(54) Vertical Comb Drive and Uses Thereof

(75) Inventors: Matan Naftali, Yoque'am (IL); David Elata, Palo Alto, CA (US)

Correspondence Address: Pearl Cohen Zedek Latzer, LLP, 1500 Broadway, 12th Floor, New York, NY, 10036, US

(73) Assignee: TECHNION RESEARCH AND DEVELOPMENT FOUNDATION LTD., Haifa (IL)

(21) Appl. No.: 10/565,980

(22) PCT Filed: Jul. 26, 2004
(86) PCT No.: PCT/IL2004/000682

§ 371 Date: Apr. 15, 2008

Related U.S. Application Data
(60) Provisional application No. 60/490,580, filed on Jul. 28, 2003.

(51) Int. Cl. H02N 1/00; B81C 1/00

(52) U.S. Cl. 310/309; 29/592.1

(57) ABSTRACT

A method for providing a vertical comb drive. The method comprises: fabricating a device comprising rotor comb element, the rotor element comb comprising a main body and a plurality of substantially parallel extensions in a comb arrangement, and at least one of a plurality of stator comb elements, comprising a main body and a plurality of substantially parallel extensions in a comb arrangement, adapted to be interlaced with the rotor, all on a single layer of a substrate.

### FIELD OF THE INVENTION

The present invention relates to the field of Micro-Optical-Electro-Mechanical-Systems (MOEMS). More particularly, the present invention relates to vertical comb drive devices.

### BACKGROUND OF THE INVENTION

Many MOEMS applications require a tilting motion of a deformable element. State-of-the-art electrostatic actuator devices are configured with an angular degree of freedom (e.g. tilting micro mirrors) and are driven by electrostatic forces. These devices are constructed from a moving part (henceforth rotor) and static parts (stators) that apply driving forces on the rotor. Such a device may be a rigid plate (rotor) suspended by a torsion bar over fixed electrodes (stators) that are parallel to the rotor. This configuration is in essence a generalization of a parallel-plate design actuator. However, such a configuration suffers from a nonlinear electromechanical response and inherent instability that decreases the controllable range of the device. The nonlinearity and instabilities that characterize the axial motion of the parallel-plates actuator can be avoided by using a double-sided comb-drive actuator to achieve a stable axial motion. This device enables in-plane motion with a linear response.

Vertical Comb-Drive actuators (VCD) attempt to generalize the working principle of the double-sided comb-drive actuator and obtain an angular motion. In a vertical comb-drive two sets of combs—the stator comb and the rotor comb—are staggered in a vertical orientation such that they can slide one into the other. The two combs comprise a free space capacitor, whereas the motion between the two combs changes the capacity of the free-space capacitor they form. Accordingly, when a voltage difference is applied between the stator and rotor combs, induced vertical electrostatic force creates a vertical motion.

Among the motivations of using vertical comb-drive actuators one is achieving a linear relation between the driving voltage and the induced angular motion. However, current vertical comb drives do not have this capability. Existing fabrication methods of VCDs also require complex and expensive micromachining processes.

Furthermore, proper operation of vertical comb-drives requires that the stator and rotor combs be perfectly aligned. Improper alignment of the stator and rotor combs may give rise to the unwarranted “side pull-in” phenomenon. Achieving a perfectly self-aligned VCD requires fabricating the entire VCD out of a single silicon layer. Current state-of-the-art fabrication methods for providing self-aligned VCDs involve applying photolithography and etching procedures. Implementation of these methods is complex, expensive resulting in excessive increase of the required driving voltage.

The motion of reflective elements of some optical MEMS applications (e.g. scanning, display and raster ring applications) is periodic as well as linear. These applications desire a “saw tooth” or a triangular waveform of the angular motion. The operation frequency of current state-of-the-art methods in MOEMS technology for achieving triangular waveforms is fixed and set by the device geometry. This complicates the modification procedure of the resonance frequency and requires post-fabrication adjustments, such as laser trimming). A method known in the art for generating a “saw tooth” waveform is summing the first, third and fifth harmonies of a sine series. However, this method is very complex, since a simultaneous actuation is required in three different degrees of freedom with perfect tuning of the different frequencies and phases.

It is thus an object of the present invention to provide a novel self-aligned vertical comb-drive actuator using a single device layer and a single machining process for reducing the cost of fabrication.

It is another object of the present invention to provide such a vertical comb-drive actuator obtaining a linear angular response.

It is another object of the present invention to provide such a vertical comb-device actuator while producing a triangular displacement waveform in resonant response and obtaining a tunable resonance frequency.

Yet another object of the present invention is to provide a simple and cost-effective method for receiving the vertical comb-drive actuator.

### BRIEF DESCRIPTION OF THE INVENTION

There is thus provided, in accordance with some preferred embodiments of the present invention, a method for providing a vertical comb drive, the method comprising:

fabricating a device comprising rotor comb element, the rotor element comb comprising a main body and a plurality of substantially parallel extensions in a comb arrangement, and at least one of a plurality of stator comb elements, comprising a main body and a plurality of substantially parallel extensions in a comb arrangement, adapted to be interlaced with the rotor, all on a single layer of a substrate.

Furthermore, in accordance with some preferred embodiments of the present invention, said at least one of a plurality of stators comprise two, substantially opposite stators, wherein the rotor is located between the two stators.

Furthermore, in accordance with some preferred embodiments of the present invention, fabricating of the device is done in a micro-machining process.

Furthermore, in accordance with some preferred embodiments of the present invention, said at least one of a plurality of stators are positioned and secured in position using glue.

Furthermore, in accordance with some preferred embodiments of the present invention, displacement limiters are used to limit displacement of the rotor.

Furthermore, in accordance with some preferred embodiments of the present invention, the displacement limiters comprise edges of slits in a surrounding body.

Furthermore, in accordance with some preferred embodiments of the present invention, the rotor and said at least one of a plurality of stators are each suspended on flexible supports.

Furthermore, in accordance with some preferred embodiments of the present invention, the flexible supports are used to reposition the rotor with respect to said at least one of a plurality of stators, so as to achieve realignment.

Furthermore, in accordance with some preferred embodiments of the present invention, the flexible supports have nonlinear kinematic-dependent rigidity.

Furthermore, in accordance with some preferred embodiments of the present invention, the rotor is provided with two substantially opposite torsion bars that define a rotation axis substantially near an external surface of the rotor.

Furthermore, in accordance with some preferred embodiments of the present invention, the external surface is an upper surface.

Furthermore, in accordance with some preferred embodiments of the present invention, the external surface is a bottom surface.

Furthermore, in accordance with some preferred embodiments of the present invention, the thickness of the extensions of said at least one of a plurality of stators is greater than the thickness of extensions of the rotor.

Furthermore, in accordance with some preferred embodiments of the present invention, the rotor is positioned in an elevated position with respect to said at least one of a plurality of stators.

Furthermore, in accordance with some preferred embodiments of the present invention, the rotor is positioned in a lowered position with respect to said at least one of a plurality of stators.

Furthermore, in accordance with some preferred embodiments of the present invention, the method further comprises controlling motion of the rotor by selecting frequencies of rotor motion thereby determining a first time interval of confined motion characterized as the time during which the motion of the rotor is limited by motion limiters and direction of motion is reversed, and a second time interval during which the motion of the rotor is not limited, and tuning the frequencies to a desired ratio between the first time interval and the second time interval.

Furthermore, in accordance with some preferred embodiments of the present invention, a driving alternating voltage is used to achieve periodic switching frequency of the rotor.

Furthermore, in accordance with some preferred embodiments of the present invention, the rotor comprises a micro-mirror.

Furthermore, in accordance with some preferred embodiments of the present invention, there is provided a vertical comb drive device comprising: a rotor comb element, the rotor element comb comprising a main body and a plurality of substantially parallel extensions in a comb arrangement, and at least one of a plurality of stator comb elements, comprising a main body and a plurality of substantially parallel extensions in a comb arrangement, adapted to be interlaced with the rotor, all on a single layer of a substrate.

### BRIEF DESCRIPTION OF THE FIGURES

In order to better understand the present invention, and appreciate its practical applications, the following Figures are provided and referenced hereafter. It should be noted that the Figures are given as examples only and in no way limit the scope of the invention. Like components are denoted by like reference numerals.

FIG. 1a illustrates elevation of stator combs using angular motion in accordance with a preferred embodiment of the present invention.

FIG. 1b illustrates lowering of the stator combs using axial motion in accordance with a second embodiment of the present invention.

FIG. 2 illustrates an angular VCD actuator known in the art, wherein the relation between the tilting angle and the driving voltage is nonlinear.

FIG. 3a illustrates an angular VCD incorporating a lowered stator, facilitating a linear relation between the tilting angle and the driving voltage.

FIG. 3b illustrates an angular VCD incorporating an elevated stator, wherein the relation between the tilting angle and the driving voltage is linear.

FIG. 4 illustrates thickening of a stator comb.

FIG. 5 illustrates the stator combs, in accordance with the present invention, used for micro-mirror application, wherein the suspension is not in contact with the stoppers (the rotor substantially parallel to the stators).

FIG. 6a illustrates the stator combs, in accordance with the present invention, whereas the suspension is in contact with the stoppers in a maximum tilted angle.

FIG. 6b is sectional view illustration of section A-A, of the device shown in FIG. 6a.

FIG. 7 is a zoom-in illustration of region B, marked in FIG. 6a.

### DETAILED DESCRIPTION OF PREFERRED EMBODIMENTS

The present invention provides a novel Vertical Comb-Drive (VCD) actuator using a single-layer device that may be manufactured in a single machining process. Moreover, the present invention discloses a simple method for manufacturing a VCD actuator having a characteristic of self-alignment between the stator and the rotor combs. Such a configuration is less complex and significantly reduces the cost of fabrication. The proposed VCD actuator is applied to obtain a linear angular response between the driving voltage and the induced angular motion. The implementation of linear devices enables an open-loop control of the angular motion, Furthermore, the proposed VCD actuator produces a triangular displacement waveform in resonant response while obtaining a tunable resonance frequency for tuning the optimal operation frequency without any post-fabrication modifications.

Reference is now made to the accompanying figures.

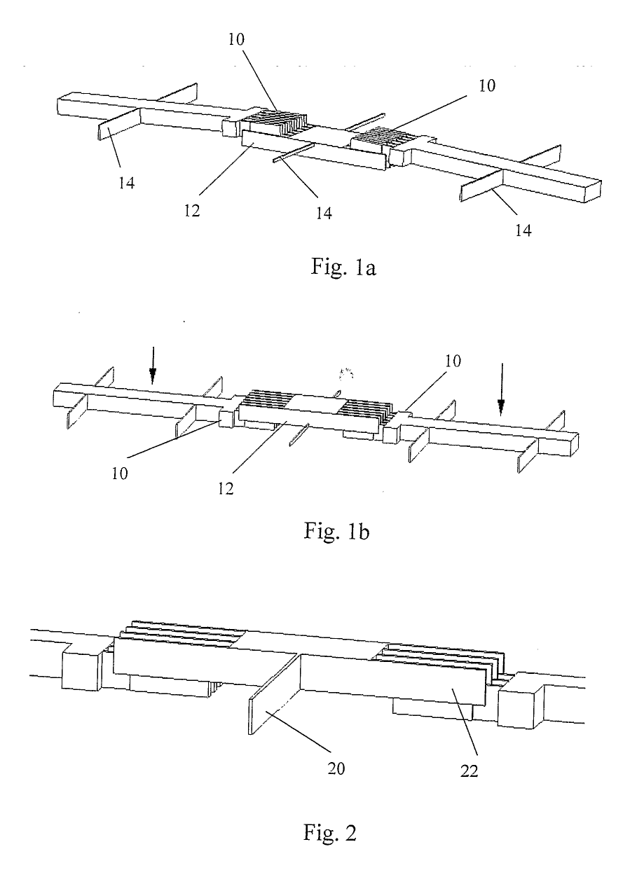

FIG. 1a illustrates elevation of the stator combs using angular motion in accordance with a preferred embodiment of the present invention. The proposed VCD actuator comprises stator combs 10, which are fabricated in the same layer and same process as the rotor 12 and like the rotor, the stator combs are also suspended on flexible supports 14. This implementation is in contrast with common VCDs, in which the stators are fabricated in their fixed final position. The flexible supports of the stators enable to lower or elevate the stators into the desired position after the micro-machining process. The micro-machining process is a mechanical process, for fabricating the stators in the same level as the rotor and repositioning them in an optimal location relative to the rotor by applying required forces. Repositioning of the stators may be carried by using angular motion, as described in this figure, or by using axial motion (see FIG. 1b). Once the stators are repositioned in their optical location, they are locked into their new position. Various means, such as using isolating glue, are provided for locking the stators into final position. The self-alignment between the rotor combs and stators is obtained by forcing the stator against displacement limiters before locking them into this final position.

FIG. 1b illustrates lowering of the stator combs using axial motion in accordance with a second embodiment of the present invention.

FIG. 2 illustrates an angular VCD actuator known in the art, whereas the relation between the tilting angle and the driving voltage is nonlinear. The rotor's torsion bar 20, according to this VCD implementation, is as thick as the rotor's layer 22 and the rotation axis is located in the middle of the device layer. Due to this axis location, the relation between the varying rotor voltage and the rotor angle is nonlinear.

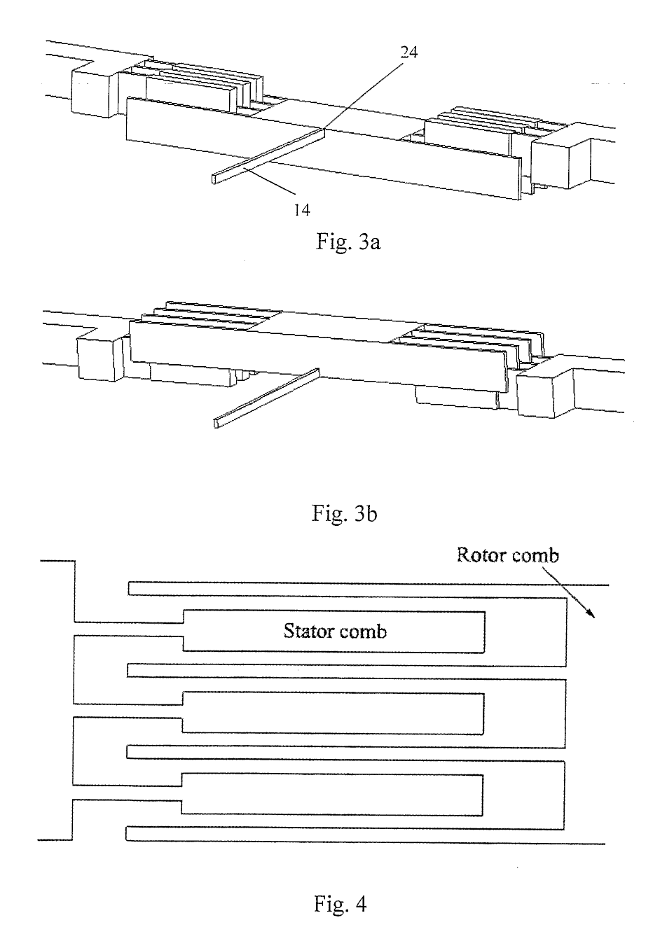

FIG. 3a illustrates an angular VCD incorporating a lowered stator, wherein the relation between the tilting angle and the driving voltage is linear. The linear angular response is obtained by applying the following principles:

The first principle involves locating the axis of rotation 24 at the surface of the rotor that is engaged with the stator. This is achieved by using a thin torsion bar 14, instead of a thick torsion bar (as shown in FIG. 2).

The second principle involves using thick stator combs (see FIG. 4), thicker than the rotor combs. These thick stator combs are further used to reduce the effect resulting from unwarranted actuation of harmonies of sine series in secondary degrees of freedom.

FIG. 3b illustrates an angular VCD including an elevated stator, wherein the relation between the tilting angle and the driving voltage is linear.

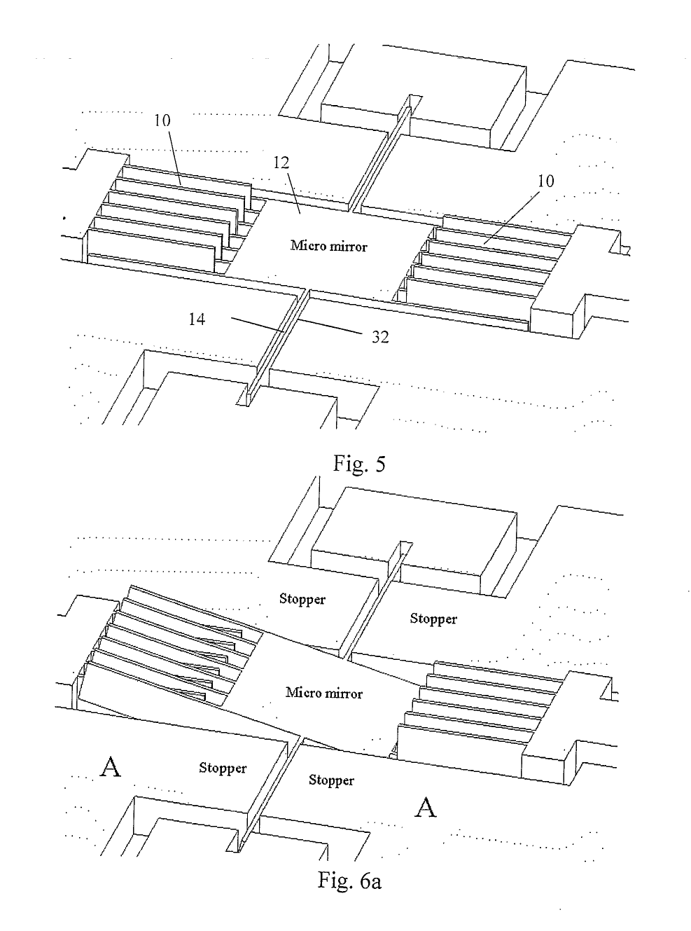

FIG. 5 illustrates the stator combs, in accordance with the present invention, whereas the suspension is not in contact with the stoppers. The device is fabricated from a single layer of a substrate 30. The rotor 12 and stators 10 are fully or partially inserted in a void in the substrate. Slits 32 are provided on either sides of the rotor, for receiving the flexible supports 14, the edges of the slit acting as stoppers, limiting the rotation of the flexible supports.

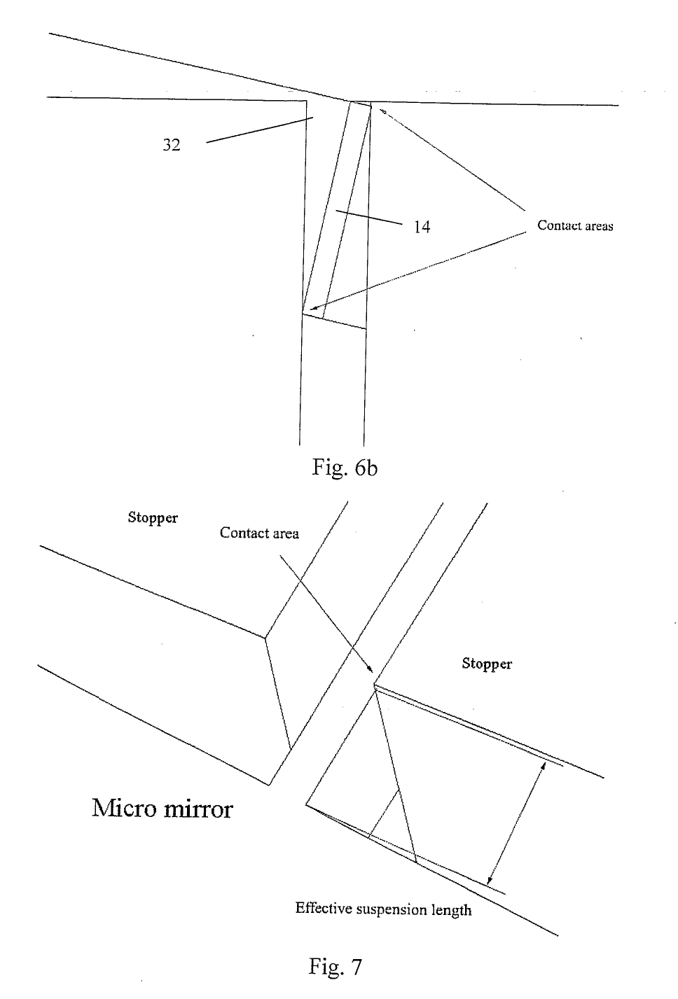

FIG. 6a illustrates the stator combs, in accordance with the present invention, whereas the suspension is in contact with the stoppers in a maximum tilted angle. The contact moment, which is developed between the stoppers 30 and the rotor 12, causes the angular velocity of the motor to rapidly decrease. Eventually, the angular velocity is reversed and the suspension is separated from the stoppers 30 in order to regain free motion in the opposite direction.

FIG. 6b is sectional view illustration of section A-A, of the device shown in FIG. 6a.

FIG. 7 is a zoom-in illustration of region B, of the device shown in FIG. 6a.

The response of rotating elements (for example micro mirrors) at resonance frequency is sinusoidal. Applying a flexible suspension with nonlinear kinematic-dependent rigidity on the sinusoidal free-motion involves a rapid velocity reversal of the sinusoidal motion. As a result, the response is converted to the desired triangular waveform. As the torsion bar 14 of the rotating element 12 tilts to its maximum desired angle, it contacts the stopper edge of slit 32 functioning as an angle limiter. Consequently, the suspension effective length decreases and its rigidity increases. As long as this contact is maintained, the sinusoidal motion of the response is defined to a confined motion.

The motion frequency depends on the ratio between the time interval of free motion and the time interval of confined motion. Therefore, the faster the rotor rotates, the more time of confined motion is required to reverse the rotor velocity, and less time is required to cover the free motion. Thus, the motion frequency depends on the overall energy of the system. By controlling the amount of energy (i.e., by controlling the amplitude of the applied driving voltage) the motion frequency can be tuned.

The driving voltages are sequentially switched to achieve the periodic tilting of the suspended mirror. To ensure that the system operates at a resonance, the switching frequency of the driving voltage must equal the angular frequency of the tilting micromirror. This is achieved by synchronizing the switching with the contact occurrences, or by other means (e.g., capacitance sensors, maximum tilt angle sensors).

It should be clear that the description of the embodiments and attached Figures set forth in this specification serves only for a better understanding of the invention, without limiting its scope.

It should also be clear that a person skilled in the art, after reading the present specification could make adjustments or amendments to the attached Figures and above described embodiments that would still be covered by the scope of the present invention.

1. A method for providing a vertical comb drive, the method comprising:
fabricating a device comprising rotor comb element, the rotor element comb comprising a main body and a plurality of substantially parallel extensions in a comb arrangement, and at least one of a plurality of stator comb elements, comprising a main body and a plurality of substantially parallel extensions in a comb arrangement, adapted to be interlaced with the rotor, all on a single layer of a substrate.

2. The method of claim 1, wherein said at least one of a plurality of stators comprise two, substantially opposite stators, wherein the rotor is located between the two stators.

3. The method of claim 1, wherein fabricating of the device is done in a micro-machining process.

4. The method of claim 1, wherein said at least one of a plurality of stators are positioned and secured in position using glue.

5. The method of claim 1, wherein displacement limiters are used to limit displacement of the rotor.

6. The method of claim 5, wherein the displacement limiters comprise edges of slits in a surrounding body.

7. The method of claim 1, wherein the rotor and said at least one of a plurality of stators are each suspended on flexible supports.

8. The method of claim 7, wherein the flexible supports are used to reposition the rotor with respect to said at least one of a plurality of stators, so as to achieve realignment.

9. The method of claim 7, wherein the flexible supports have nonlinear kinematic-dependent rigidity.

10. The method of claim 1, wherein the rotor is provided with two substantially opposite torsion bars that define a rotation axis substantially near an external surface of the rotor.

11. The method of claim 10, wherein the external surface is an upper surface.

12. The method of claim 11, wherein the external surface is a bottom surface.

13. The method of claim 1, wherein the thickness of the extensions of said at least one of a plurality of stators is greater than the thickness of extensions of the rotor.

14. The method of claim 1, wherein the rotor is positioned in an elevated position with respect to said at least one of a plurality of stators.

15. The method of claim 1, wherein the rotor is positioned in a lowered position with respect to said at least one of a plurality of stators.

16. The method of claim 1, further comprising controlling motion of the rotor by selecting frequencies of rotor motion thereby determining a first time interval of confined motion characterized as the time during which the motion of the rotor is limited by motion limiters and direction of motion is reversed, and a second time interval during which the motion of the rotor is not limited, and tuning the frequencies to a desired ratio between the first time interval and the second time interval.

17. The method of claim 1, wherein a driving alternating voltage is used to achieve periodic switching frequency of the rotor.

18. The method of claim 1, wherein the rotor comprises a micro-mirror.

19. A vertical comb drive device comprising:
a rotor comb element, the rotor element comb comprising a main body and a plurality of substantially parallel extensions in a comb arrangement, and at least one of a plurality of stator comb elements, comprising a main body and a plurality of substantially parallel extensions in a comb arrangement, adapted to be interlaced with the rotor, all on a single layer of a substrate.

20. The device of claim 19, wherein said at least one of a plurality of stators comprise two, substantially opposite stators, wherein the rotor is located between the two stators.

21. The device of claim 19, wherein said at least one of a plurality of stators are positioned and secured in position using glue.

22. The device of claim 19, wherein displacement limiters are used to limit displacement of the rotor.

23. The device of claim 22, wherein the displacement limiters comprise edges of slits in a surrounding body.

24. The device of claim 19, wherein the rotor and said at least one of a plurality of stators are each suspended on flexible supports.

25. The device of claim 24, wherein the flexible supports are used to reposition the rotor with respect to said at least one of a plurality of stators, so as to achieve realignment.

26. The device of claim 24, wherein the flexible supports have nonlinear kinematic-dependent rigidity.

27. The device of claim 19, wherein the rotor is provided with two substantially opposite torsion bars that define a rotation axis substantially near an external surface of the rotor.

28. The device of claim 27, wherein the external surface is an upper surface.

29. The device of claim 27, wherein the external surface is a bottom surface.

30. The device of claim 19, wherein the thickness of the extensions of said at least one of a plurality of stators is greater than the thickness of extensions of the rotor.

31. The device of claim 19, wherein the rotor is positioned in an elevated position with respect to said at least one of a plurality of stators.

32. The device of claim 19, wherein the rotor is positioned in a lowered position with respect to said at least one of a plurality of stators.

33. The device of claim 19, wherein a driving alternating voltage is used to achieve periodic switching frequency of the rotor.

34. The device of claim 19, wherein the rotor comprises a micro-mirror.

35-36. (canceled)
